(19) United States
(12) Patent Application Publication
(10) Pub. No.: US 2012/0286764 A1
(43) Pub. Date: Nov. 15, 2012

(54) APPARATUS FOR DETECTING PARTIAL DISCHARGE FOR ELECTRIC POWER DEVICES

(75) Inventors: Eun Tae Lyu, Gyeonggi-do (KR); Kyung Rok Hwang, Gyeonggi-do (KR); Min Soo Kim, Gyeonggi-do (KR); Hang Jun Yang, Gyeonggi-do (KR)

(73) Assignee: HYOSUNG CORPORATION, Gyeonggi-do (KR)

(21) Appl. No.: 13/519,637

(22) PCT Filed: Dec. 24, 2010
(86) PCT No.: PCT/KR10/09330

§ 371 Date: Jun. 28, 2012

(30) Foreign Application Priority Data
Dec. 28, 2009 (KR) 10-2009-0132198

(51) Int. Cl. G01R 29/00

(52) U.S. Cl. 324/76.11

(57) ABSTRACT

The present invention relates to an apparatus for detecting partial discharge for electric power devices, comprising: an insulator having a predetermined shape; a receiving unit arranged inside or outside the insulator to receive signals of a plurality of sub-bands; and a connection electrode which transmits signals of a receiving electrode to a coaxial cable in conjunction with the connected coaxial cable.

### PRIORITY CLAIM

The present application is a National Phase entry of PCT Application No. PCT/KR2010/009330, filed Dec. 24, 2010, which claims priority from Korean Application No 10-2009-0132198, filed Dec. 28, 2009, the disclosures of which are hereby incorporated by reference herein in their entirety.

### TECHNICAL FIELD

The present invention relates to an apparatus for detecting partial discharge for an electric power device, and more particularly, to a partial discharge detecting apparatus for an electric power device that may measure signals of multiple frequency bands in which the electric power device may correspond to a power transformer and the electric power device may include a rotary device, a motor, a generator, and the like.

### BACKGROUND OF THE INVENTION

A general partial discharge detecting apparatus for a power transformer may be installed inside an electric power device while maintaining a predetermined insulating distance and thereby detect a partial discharge signal.

An installation type of the detecting apparatus may be classified into two types based on an installation location.

When an installation location corresponds to an upper portion of a high power transformer, the conventional partial discharge detecting apparatus may prevent leakage of insulating oil and may stably detect a partial discharge signal in a state where the insulating oil is filled. Also, the conventional partial discharge detecting apparatus may detect a partial discharge signal using a receiving unit having a wide width, such as a sensor applied to a gas insulating device. In addition, when an inspection window provided to the conventional partial discharge detecting apparatus is the same as the gas insulating device, the inspection window may be used compatibly with a partial discharge detecting apparatus of the gas insulating device.

Also, when an installation location corresponds to an inside of a drain valve of a power transformer, the conventional partial discharge detecting apparatus may not additionally include a separate inspection window and a sensor may be installed at various locations, for example, an upper portion, a lower portion, a side, and the like. In this case, the conventional partial discharge detecting apparatus is installed in a state where leakage of insulating oil is prevented using a valve and thus, may be stably mounted.

FIGS. 1 and 2 are views illustrating the conventional partial discharge detecting apparatus.

Referring to FIG. 1, a conventional partial discharge detecting apparatus 10 is installed in an upper portion of a power transformer.

The partial discharge detecting apparatus 10 may include a receiving unit 11 and inspection windows 12 and 13, and may transmit, via an N-type connector 14 and a coaxial cable 15, a signal that is detected from the power transformer.

Referring to FIG. 2, a conventional partial discharge detecting apparatus 20 is installed in a drain valve.

Here, the partial discharge detecting apparatus 20 may separately include a signal unit end 21 and a signal output end 22, and may include a receiving unit 23a connected to an input and a receiving unit 23b connected to an output in a parallel coupler form.

However, when a partial discharge detecting apparatus is installed in an upper portion of a power transformer, a sensor may not be installed. Even though a sensor may be installable, the range of partial discharge signal detection may be restricted due to a limited installation location of the sensor. Also, a partial discharge signal occurring in a lower portion of the power transformer may be attenuated due to a distance and an internal constituent element, for example, due to the affect of insulating oil, winding, and the like. Accordingly, it may be difficult to detect a signal.

On the contrary, when the partial discharge detecting apparatus is installed in a drain valve, an input and an output may be separately provided and thus, the partial discharge detecting apparatus may have a coupler function in addition to an antenna function to thereby be capable of injecting a signal and obtaining an output signal. In this case, the partial discharge detecting apparatus is installed in a drain valve capable of preventing leakage of insulating oil to thereby have a structure in which installation and separation may be readily performed.

Meanwhile, the partial discharge detecting apparatus is generally configured in a form of a circle, two semicircles having the same shape, or a long monopole and thus, may have difficult in detecting a wideband signal.

Also, the partial discharge detecting apparatus is configured in a unit shape and the same shape to be capable of having the fixed wavelength. In particular, a size of a dipole antenna structure may be determined based on a length of a wavelength shown in FIG. 3. In this case, the partial discharge detecting apparatus has a narrow bandwidth having a unit resonant frequency and thus, may have some constraints in detecting a partial discharge signal of a wide band in the case of detecting the partial discharge.

A frequency band in which the partial discharge occurs is generally 0.5 GHz to 1.5 GHz and a wideband characteristic is required to receive a signal of a wide frequency band. However, when the partial discharge detecting apparatus is configured in the unit shape and the same shape, the wavelength is physically constrained to have a wideband and thus, it may be difficult to configure the partial discharge detecting apparatus.

### SUMMARY OF THE INVENTION

Embodiments of the present invention provide an apparatus for detecting partial discharge that may detect a partial discharge signal of an electric power device, for example, a power transformer through a plurality of sub-bands.

Also, embodiments of the present invention provide an apparatus for detecting partial discharge for an electric power device that may selectively detect a partial discharge signal of a designated frequency band.

According to an aspect of the present invention, there is provided an apparatus for detecting partial charge for an electric power device, the apparatus including: an insulator having a predetermined shape; a receiving unit including at least one receiving electrode that is installed inside or outside the insulator to receive a signal of each of at least one sub-band; and a connection electrode to transmit a signal of each of the at least one receiving electrode to a coaxial cable in conjunction with the connected coaxial cable.

Here, the at least one sub-band may correspond to a plurality of signal bands that is divided to detect a partial discharge signal of a power transformer in the entire frequency band.

Also, the receiving unit may be provided in a monopole structure.

Also, the receiving unit may include the at least one receiving electrode to receive a signal of each sub-band.

Also, each of the at least one receiving electrode may have a different wavelength to measure a signal of each sub-band.

Also, the at least one receiving electrode may be disposed to face each other based on the insulator.

According to embodiments of the present invention, a partial discharge detecting apparatus may process a frequency signal of a wideband by receiving signals of a wide frequency band via a plurality of sub-bands.

Also, according to embodiments of the present invention a partial discharge detecting apparatus may be configured to detect a signal of a desired band by selectively installing a receiving electrode having a different wavelength for each sub-band.

### BRIEF DESCRIPTION OF THE DRAWINGS

FIGS. 1 and 2 are views illustrating a conventional partial discharge detecting apparatus;

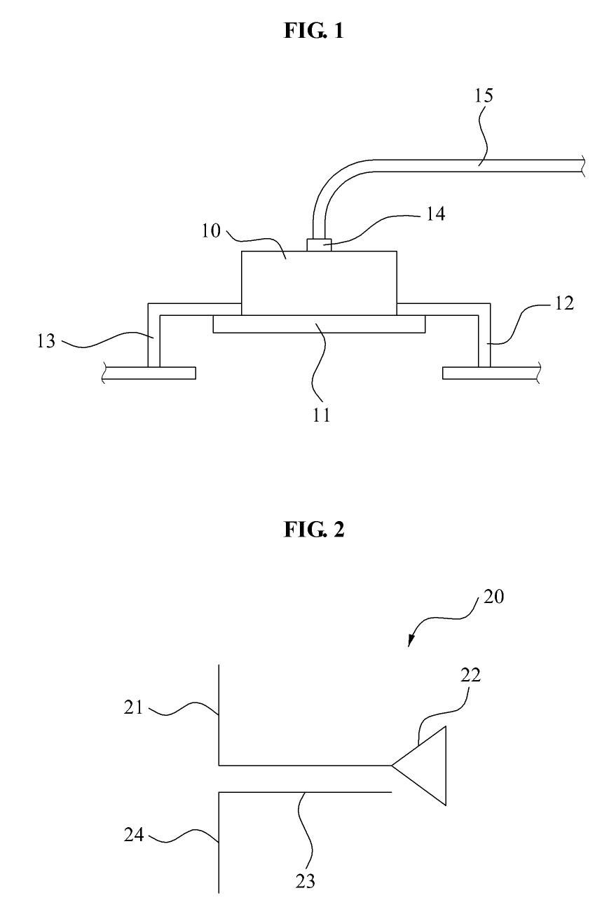

FIG. 3 is a view illustrating an irradiation shape of a dipole antenna;

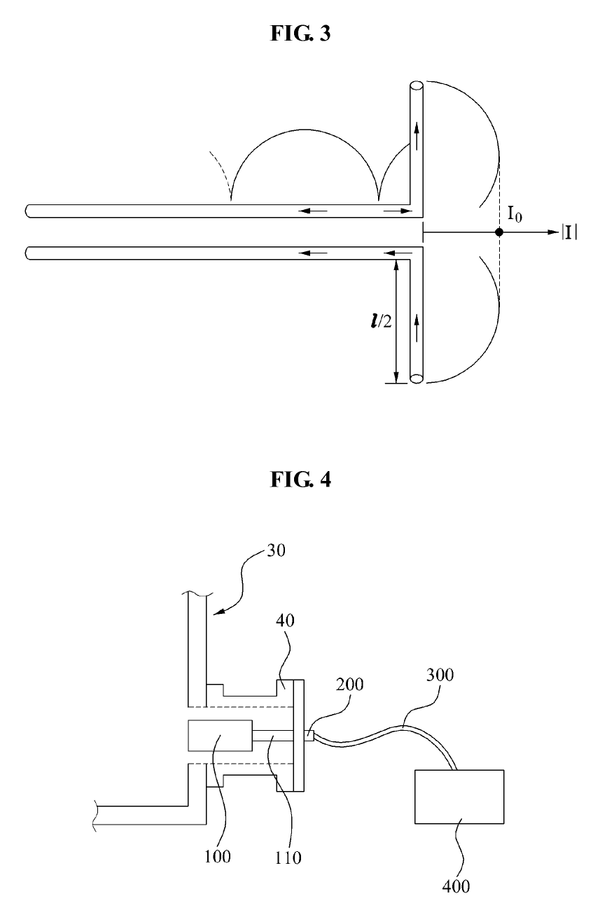

FIG. 4 is a view illustrating a partial discharge detecting apparatus according to an embodiment of the present invention;

FIGS. 5A and 5B, and FIG. 6 are exemplary views showing a configuration of the partial discharge detecting apparatus of FIG. 4;

FIGS. 7A and 7B, and FIG. 8 are exemplary views showing a configuration of the partial discharge detecting apparatus of FIG. 4; and

FIG. 9 is a graph showing a return loss of a partial discharge detecting apparatus according to an embodiment of the present invention.

### DETAILED DESCRIPTION

Hereinafter, embodiments of the present invention will be described with reference to the accompanying drawings. When it is determined detailed description related to a related known function or configuration they may make the purpose of the present invention unnecessarily ambiguous in describing the present invention, the detailed description will be omitted here. Also, terminologies used herein are defined to appropriately describe the exemplary embodiments of the present invention and thus may be changed depending on a user, the intent of an operator, or a custom. Accordingly, the terminologies must be defined based on the following overall description of this specification.

A partial discharge detecting apparatus according to an embodiment of the present invention may be applicable to a power electric device. The power electric device may correspond to a power transformer. Also, the power electric device may include a rotary device, a motor, a generator, and the like. Hereinafter, for ease of description, a description will be made using the power transformer as the power electric device applied with the partial discharge detecting apparatus.

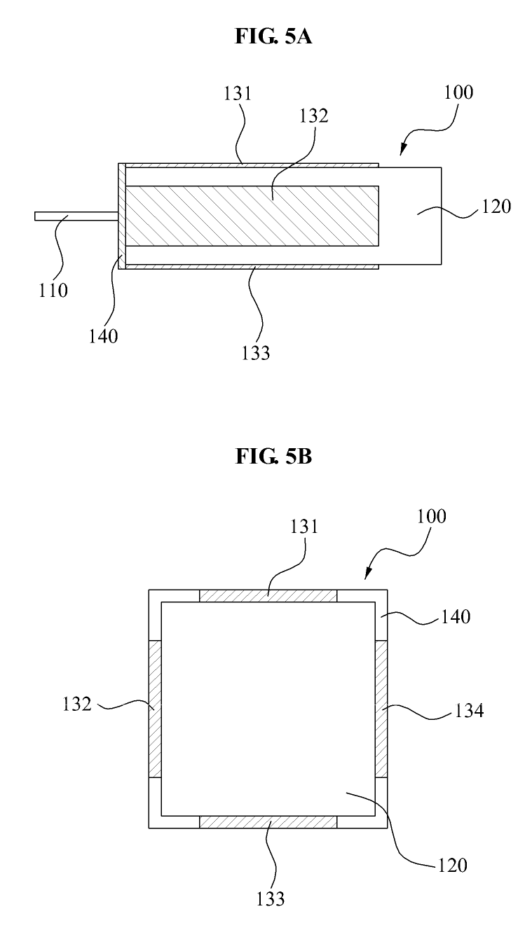

FIG. 4 is a view illustrating a partial discharge detecting apparatus according to an embodiment of the present invention.

Referring to FIG. 4, the partial discharge detecting apparatus 100 may be installed in an upper portion of a power transformer 30 or a lower drain valve 40.

The partial discharge detecting apparatus 100 may interact with a partial discharge signal processing apparatus 400 via an N-type connector 200 and a coaxial cable 300.

To detect a partial discharge signal band, for example, 0.5 GHz to 1.5 GHz and an ultra-high frequency (UHF) band, occurring in the power transformer, the partial discharge detecting apparatus 100 may include a receiving unit to detect a signal of each of multiple sub-bands.

In particular, the receiving unit of the partial discharge detecting apparatus 100 may be provided for each of the plurality of sub-bands of the partial discharge signal band, for example, four frequency bands including a first band of 0.5 GHz to 0.75 GHz, a second band of 0.75 GHz to 1.00 GHz, a third band of 1.00 GHz to 1.25 GHz, and a fourth band of 1.25 GHz to 1.5 GHz.

Here, a structure of the receiving unit may be configured as one of a meander-line structure, a rectangular spiral structure, and a symmetrical structure in which the same electrodes face each other. Due to characteristics, the structure of the receiving unit may have a wide wavelength with a narrow area. The receiving unit may be attached on an outside of an insulator of the partial discharge detecting apparatus 100 or may be inserted into the partial discharge detecting apparatus 100.

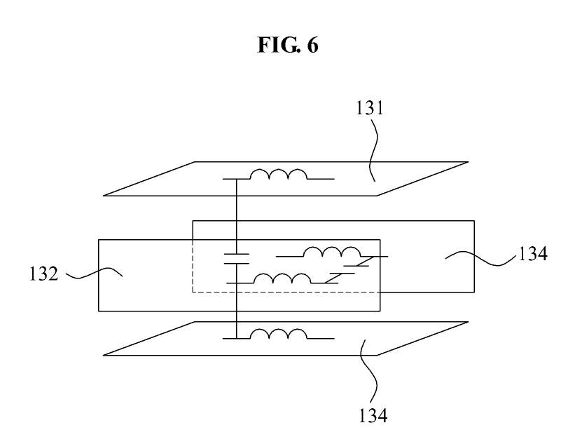

FIGS. 5A and 5B show the partial discharge detecting apparatus 100 in a case where a receiving unit is installed outside an insulator.

FIG. 5A shows a longitudinal-side view of the partial discharge detecting apparatus 100, and FIG. 5B shows a cross-sectional view of the partial discharge detecting apparatus 100.

Referring to FIGS. 5A and 5B, the partial discharge detecting apparatus 100 may include an insulator 120, a receiving unit (131 to 133), a lower electrode 140, and a connection electrode 110.

The insulator 120 may be configured in a predetermined shape, for example, an equiangular shape such as a rectangular shape or a hexagonal shape, and may be formed using acryl or epoxy solid against heat.

The receiving unit (131 to 134) may be provided inside or outside the insulator 120 to receive a signal of each of a plurality of sub-bands.

Also, the receiving unit (131 to 134) may include at least one receiving electrode, for example, receiving electrodes 131 to 134, to receive a signal of each sub-band.

The sub-band may correspond to a plurality of signal bands for detecting a partial discharge signal of the power transformer in the entire frequency band. The receiving electrodes 131 to 134 may be provided for the respective sub-bands.

Aluminum and stainless materials may be used as a material of the receiving electrodes 131 to 134 to minimize erosion occurring due to insulating oil. Each of the receiving electrodes 131 to 134 may be positioned to surround the insulator 120 and be connected to the lower electrode 140. The lower electrode 140 may be connected to the N-type connector 200 via the connection electrode 110.

In addition, each of the receiving electrodes 131 to 134 may be configured to have a ¼ wavelength of a different band. Accordingly, the partial discharge detecting apparatus may detect signals of multiple bands.

Referring to FIG. 6, since the receiving electrodes 131 to 134 have different wavelengths, different inductance may be formed.

Also, the receiving electrodes 131 to 134 may be disposed to face each other based on the insulator 120. Accordingly, capacitance may be present between predetermined receiving electrodes, for example, between the receiving electrodes 131 and 133, and between the receiving electrodes 132 and 134.

Accordingly, a predetermined parallel resonance circuit may be formed in the receiving electrodes 131 to 134 that function as a receiving unit of an antenna.

In particular, the receiving electrodes 131 to 134 have the same clearance based on the insulator 120 and thus, the same capacitance may be present. However, the entire resonance circuit may have different resonant frequencies due to inductance that forms different wavelengths.

That is, inductance of the receiving electrode 131 may form different four resonant frequencies overall. Since a parallel resonance circuit corresponds to adjacent four parallel circuits, an additional band may be formed due to interaction between adjacent circuits.

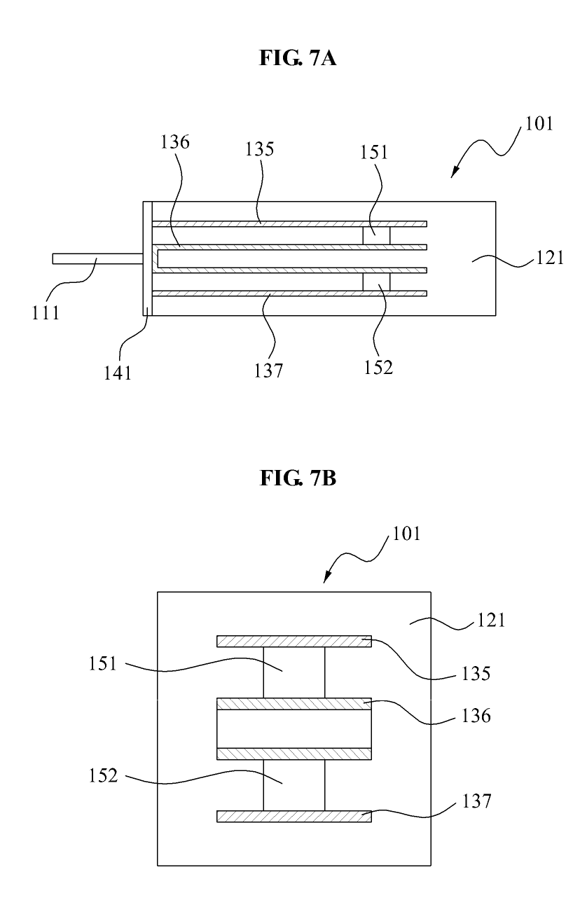

Meanwhile, FIGS. 7A and 7B show a partial discharge detecting apparatus 101 in a case where a receiving unit (135 to 137) is provided inside an insulator 121.

Referring to FIGS. 7A the partial discharge detecting apparatus 101 may include a lower electrode 141, and a connection electrode 111.

FIG. 7A shows a longitudinal-side view of the partial discharge detecting apparatus 101, and FIG. 7B shows a cross-sectional view of the partial discharge detecting apparatus 101.

Referring to FIGS. 7A and 7B, the receiving unit (135 to 137, 151, and 152) of the partial discharge detecting apparatus 101 may be provided inside the insulator 121 and be fixed to be in parallel with each other.

For this, the receiving unit (135 to 137, 151, and 152) may include a plurality of receiving electrodes 135 to 137 and at least one parallel maintaining electrode, for example, parallel maintaining electrodes 151 and 152.

The receiving electrodes 135 to 137 may be installed inside the insulator 121, and a plurality of electrode boards may be provided to be in parallel with each other in order to be capable of receiving a signal for each sub-band.

The parallel maintaining electrodes 151 and 152 may be inserted to maintain a parallel relationship between the respective receiving electrodes 135 to 137, and may be formed using the same material as the receiving electrodes 135 to 137.

Also, the insulator 121 may be configured to mold the internally installed receiving unit (135 to 137, 151, and 152).

The insulator 121 may be formed using a material having a high conductivity such as copper, aluminum, and stainless to prevent the molded receiving unit (135 to 137, 151, and 152) from being eroded due to insulating oil.

The receiving electrodes 135 to 137 may be arranged inside the insulator 121 to be in parallel with each other at predetermined intervals, and may be connected to each other via the respective connection electrodes 151 and 152.

Accordingly, as shown in FIG. 8, the receiving electrodes 135 to 137 may maintain the capacitance between the respective receiving electrodes at predetermined intervals.

In particular, since the receiving electrodes, for example, an upper board of the receiving electrode 136 and the receiving electrode 135 and a lower board of the receiving electrode 136 and the receiving electrode 137 that are arranged to be in parallel with each other have different inductance, a multi-resonance circuit may be present. When a partial discharge signal is to be detected using the receiving electrode 135, a wideband detecting apparatus may be required and a multi-resonance scheme may be employed to configure the above purpose.

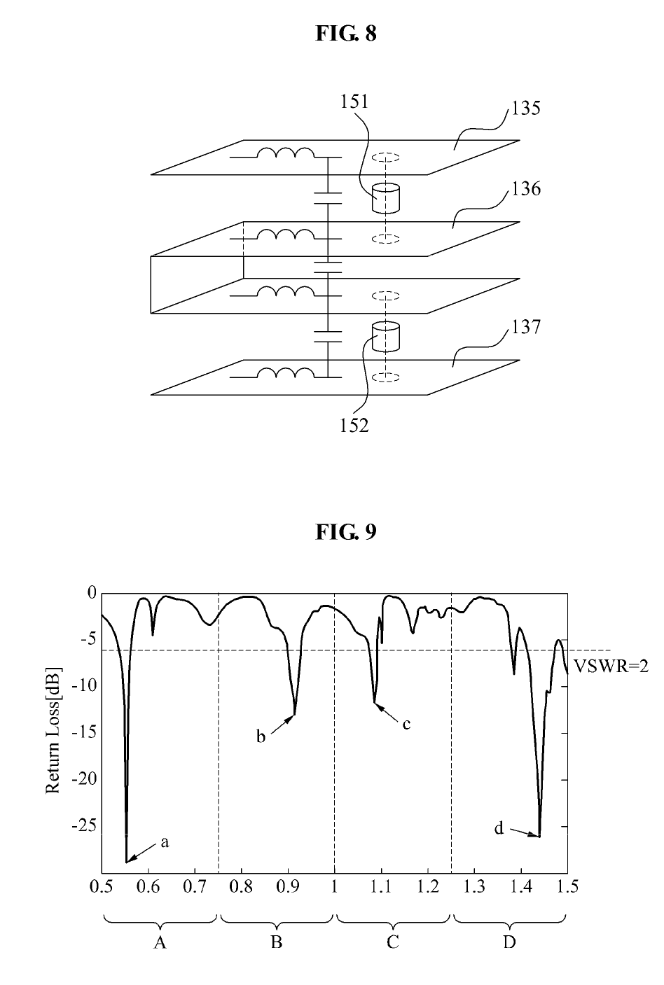

FIG. 9 is a graph showing a return loss of a partial discharge detecting apparatus according to an embodiment of the present invention.

Referring to FIG. 9, the return loss graph shows a test result that is obtained by connecting the partial discharge detecting apparatus 100 or 101 to a chamber for simulation test of a power transformer, and shows signals that are measured using four sub-bands A to D.

Here, each of the sub-bands A to D may be designed to be suitable for a ¼ wavelength of a resonant frequency for each band. According to an embodiment of the present invention, four frequency bands may include a first band of 0.5 GHz to 0.75 GHz, a second band of 0.75 GHz to 1.00 GHz, a third band of 1.00 GHz to 1.25 GHz, and a fourth band of 1.25 GHz to 1.5 GHz.

Consequently, it can be known from the return loss graph that it is possible to detect resonant frequencies a to d within the respective sub-bands A to D.

In addition, the partial discharge detecting apparatus 100 or 101 may also be configured to detect a signal of only a predetermined band. For example, by providing each of the receiving electrodes 131 to 137 of the partial discharge detecting apparatus 100 or 101 for each predetermined band, the partial discharge detecting apparatus 100 or 101 may selectively detect a signal of a frequency band designated by a user or a developer, instead of detecting a signal of a consecutive frequency band.

The exemplary embodiments according to the present invention may be recorded in computer-readable media including program instructions to implement various operations embodied by a computer. The media may also include, alone or in combination with the program instructions, data files, data structures, and the like. The media and program instructions may be those specially designed and constructed for the purposes of the present invention, or they may be of the kind well-known and available to those having skill in the computer software arts.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. An apparatus for detecting partial charge for an electric power device, the apparatus comprising:
an insulator having a predetermined shape;
a receiving unit including at least one receiving electrode that is installed inside or outside the insulator to receive a signal of each of at least one sub-band; and
a connection electrode to transmit a signal of each of the at least one receiving electrode to a coaxial cable in conjunction with the connected coaxial cable.

2. The apparatus of claim 1, wherein the at least one sub-band corresponds to a plurality of signal bands that is divided to detect a partial discharge signal of a power transformer in the entire frequency band.

3. The apparatus of claim 1, wherein the receiving unit is provided in a monopole structure.

4. The apparatus of claim 1, wherein the receiving unit includes the at least one receiving electrode to receive a signal of each sub-band.

5. The apparatus of claim 4, wherein each of the at least one receiving electrode has a different wavelength to measure a signal of each sub-band.

6. The apparatus of claim 4, wherein the at least one receiving electrode is disposed to face each other based on the insulator.

7. The apparatus of claim 1, wherein the electric power device corresponds to a power transformer.

8. The apparatus of claim 1, wherein the receiving unit comprises:
a plurality of receiving electrodes installed inside the insulator to receive a signal for each sub-band; and
parallel maintaining electrodes to maintain a parallel relationship between the plurality of receiving electrodes.

9. The apparatus of claim 8, wherein the plurality of receiving electrodes maintains capacitance and has different inductance.

10. The apparatus of claim 9, wherein the plurality of receiving electrodes configures a multi-resonance circuit to form different four resonant frequencies.
